(19) United States
(12) Patent Application Publication
(10) Pub. No.: US 2011/0260230 A1
(43) Pub. Date: Oct. 27, 2011

(54) CELL WITH SURROUNDING WORD LINE STRUCTURES AND MANUFACTURING METHOD THEREOF

(75) Inventors: TZUNG HAN LEE, TAIPEI CITY (TW); CHUNG-LIN HUANG, TAOYUAN COUNTY (TW); HSIEN-WEN LIU, TAOYUAN COUNTY (TW)

(73) Assignee: INOTERA MEMORIES, INC., Taoyuan County (TW)

(21) Appl. No.: 12/829,674

(22) Filed: Jul. 2, 2010

(30) Foreign Application Priority Data
Apr. 23, 2010 (TW) 99112970

(51) Int. Cl. H01L 27/108; H01L 21/8242

(52) U.S. Cl. 257/306; 438/253; 257/E27.084; 257/E21.646

(57) ABSTRACT

A memory cell with surrounding word line structures includes an active area; a plurality of first trenches formed on the active area in a first direction, each first trench has a bit line on a sidewall therein; a plurality of second trenches formed on the active area in a second direction, each second trench has two word lines formed correspondingly on the sidewalls in the second trench; and a plurality of transistors formed on the active area. The word line pairs are arranged into a surrounding word line structure. The transistor is controlled by the bit line and the two word lines, thus improving the speed of the transistor.

### BACKGROUND OF THE INVENTION

1. Field of the Invention

The present invention is a cell with surrounding word line structures and the manufacturing method thereof; especially, the present invention relates to cell having improved speed and the manufacturing method thereof.

2. Description of Related Art

The memory cells of DRAM usually have FET devices and capacitors. In other words, the cell is consisted of a capacitor and a transistor for controlling the charging/discharging and reading. The transistor is controlled by word lines and bit lines. It plays an important role for improving the on/off speed of the transistor.

In the traditional cell structure, bit lines are formed on both sides of the trench; therefore, the size of one bit line is limited. The smaller bit line results in the higher resistance and further in the lower speed. On the other hand, only a word line is formed to control the on/off of the transistor. Therefore, the switching rate of the transistor is lower.

Consequently, with regard to the resolution of defects illustrated hereinbefore, the inventors of the present invention propose a reasonably and effectively designed solution for effectively eliminating such defects.

### SUMMARY OF THE INVENTION

The objective of the present invention is to provide a memory cell characterized in surrounding word line structures that the speed of the transistor can be increased.

To achieve the objective described as above, the present invention discloses a manufacturing method for a cell with surrounding word line structures, comprising the steps of:

Step 1: providing an active area;

Step 2: forming a plurality of first trenches in the active area and the first trenches extending along a first direction, and forming a bit line on a side of each the first trench;

Step 3: forming a plurality of second trenches in the active area and the second trenches extending along a second direction, and forming two word lines respectively on two sides of each the second trench; and

Step 4: forming a plurality of transistors in the active area; wherein each the transistor is controlled by two gates defined of the two word lines and one of the bit lines for increasing switching rates.

In an embodiment, a trench sidewall implant step and an etch back step are provided for forming the single bit line on a side of the first trench. Furthermore, steps of forming a pad on the transistor and forming capacitor on the pad are provided after the Step 4.

The present invention further provides a cell with surrounding word line structures, comprising: an active area; a plurality of first trenches formed in the active area and extending in a first direction; wherein each the first trench has a bit line on a side thereof; a plurality of second trenches formed in the active area and extending in a second direction; wherein each the second trench has two word lines respectively formed on two sides of the second trench; and a plurality of transistors formed in the active area; wherein each the transistor is controlled by the bit line and the two word lines, the word lines are constructed to the surrounding word line structures, and each the transistor is controlled by two gates defined of the two word lines for increasing switching rates.

The transistor of the present invention is controlled by two word lines and one bit line. The single bit line having lower resistance and the two channels defined by the two word lines result in the higher speed of the memory cell.

In order to further appreciate the characteristics and technical contents of the present invention, references are hereunder made to the detailed descriptions and appended drawings in connection with the present invention. However, the appended drawings are merely shown for exemplary purposes, rather than being used to restrict the scope of the present invention.

### BRIEF DESCRIPTION OF THE DRAWINGS

FIG. 1A to 1C are structural diagrams of manufacturing the bit line according to the present invention;

FIG. 2A to 2F show the practice steps of manufacturing the bit line according to the present invention;

FIG. 3A to 4B are structural diagrams of manufacturing the word line according to the present invention;

FIG. 5 illustrates the step of manufacturing transistor according to the present invention;

FIG. 6A to 6B are structural diagrams of manufacturing the pad according to the present invention;

FIG. 7A to 7B are structural diagrams of manufacturing the capacitor according to the present invention;

FIG. 8 illustrates the surrounding gate structure according to the present invention.

### DETAILED DESCRIPTION OF THE PREFERRED EMBODIMENTS

The present invention provides a memory cell having surrounding word line structures and a manufacturing method thereof. The memory cell has two gates (i.e., word lines) on two sides of a transistor. The gates define a pair of channel that can increase the switching rate of the transistor. Furthermore, the transistor is controlled by a single bit line having a lager size than the traditional bit line pair. Therefore, the digital line defined by the larger bit line of the present invention has an improved transfer rate.

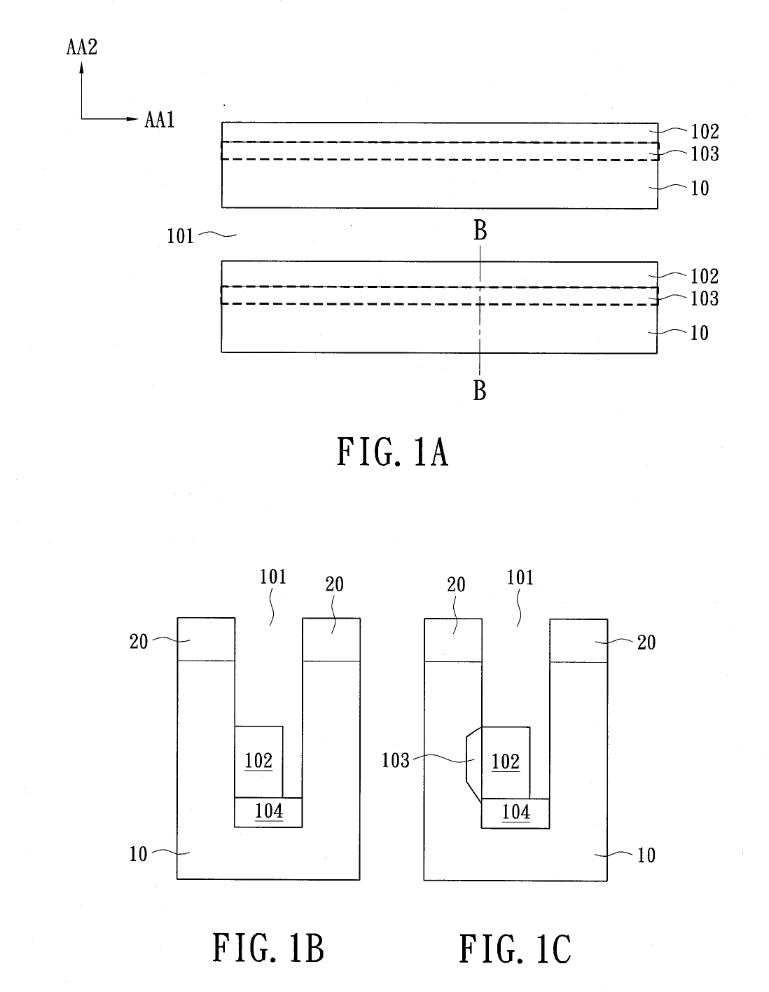

Please refer to FIGS. 1A to 7B. The method of manufacturing the memory cell according to the instant disclosure is discussed as follows.

First, providing an active area 10 and forming a plurality of first trenches 101 along a first direction on the active area 10. As shown in FIG. 1A, the direction AA1 is chosen to be the first direction. Next, forming a bit line 102 on a sidewall in the first trench 101. Comparing to the traditional structure where a pair of bit lines is used, the bit line 102 in the instant disclosure is a single line having a larger dimension. That means the resistance of the bit line 102 is reduced and the digital line defined by the larger bit line 102 of the present invention can have higher transfer rates. It is noted that a mask, such as a hard mask 20, is shown in FIGS. 1B and 1C.

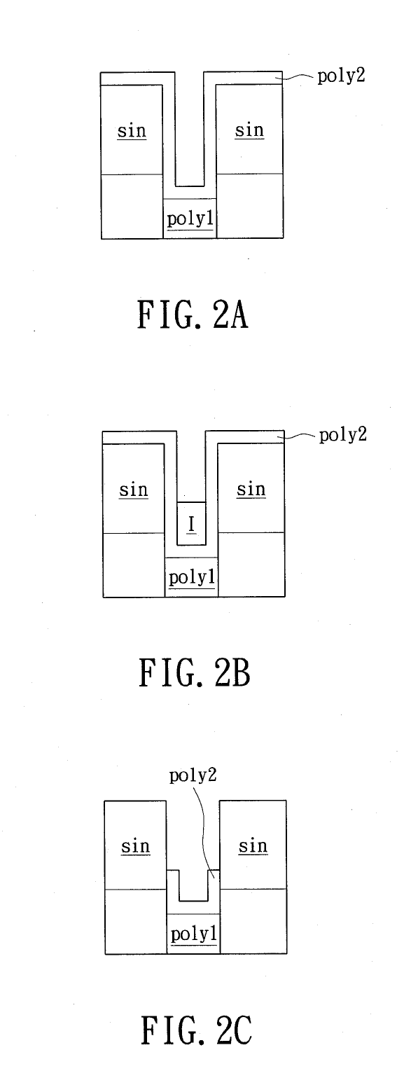

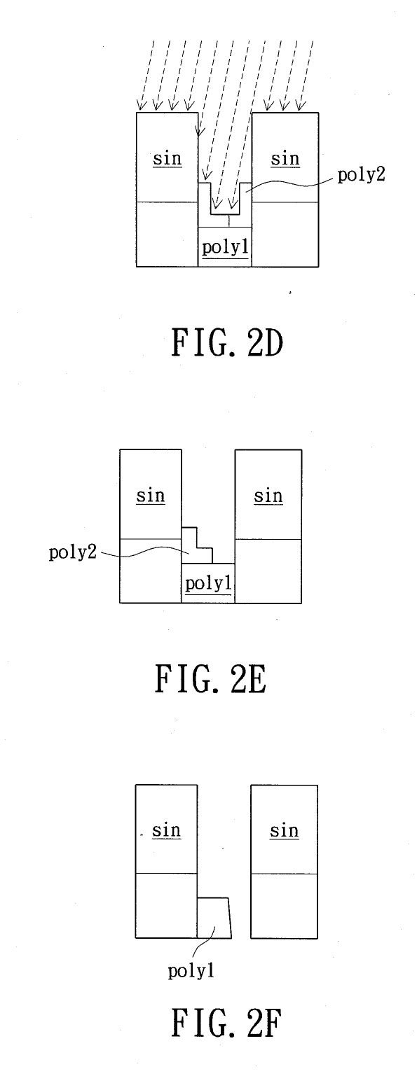

FIGS. 2A to 2F illustrate the steps for manufacturing the single bit line 102 on one side of the first trench 101. Referring to FIG. 2A; the trench has a poly-layer poly1 on the bottom and a SiN layer on the sides. A poly-layer poly2 is formed on poly1 and the SiN layers. Referring to FIG. 2B, an etch-isolation layer “I” is disposed in the trench. Referring to FIG. 2C, an etching process is carried out to remove part of poly2 exposing from the etch-isolation layer “I”. Subsequently, the etch isolation layer “I” is also removed. Thus, only part of poly2 remains in the trench. Referring to FIG. 2D, a sideway ion-implantation procedure is performed to partially modify the remained ploy2. Then referring to FIG. 2E, another etching procedure is carried out to remove the un-modified part of the poly2. The modified part of poly 2 may not be removed by the etchant, and therefore remains in the trench. Finally, referring to FIG. 2F, an etch-back step is carried out to remove a part of the poly1 that is exposed from poly2. Accordingly, the remaining part of the poly1 forms the single bit line 102 of the instant disclosure. The applicable etch-back methods includes SOD etch back, TEOS etch back, SOG annealing, poly deposition, CMP, and so on.

The first trench 101 further has a shallow trench isolation layer (STI) 104 on a bottom thereof. The STI 104 may be an oxide layer on which the bit line 102 is formed.

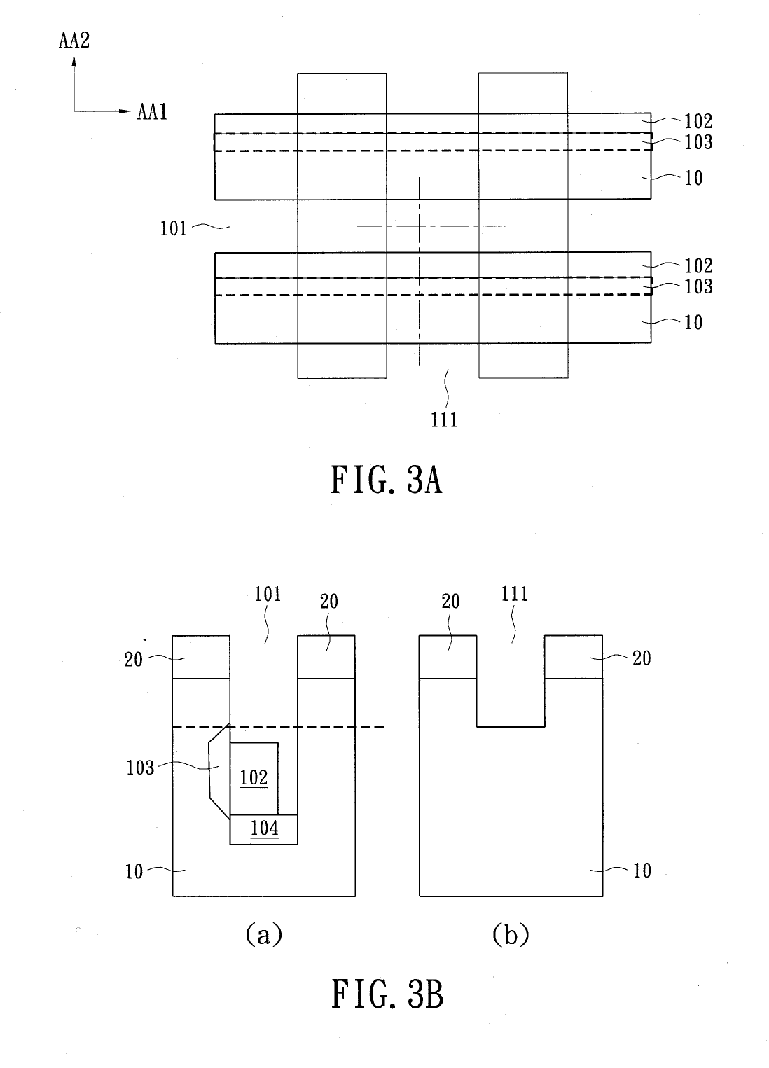

In addition, a step of forming an out-diffusion junction 103 in the sidewall of the first trench 101 is performed after the formation of the bit line 102. The position of the out-diffusion junction 103 corresponds to the position of the bit line 102 as illustrated in FIG. 3A and 3B.

Referring further to FIGS. 3A-3B; a plurality of second trenches 111 is formed in a second direction on the active area 10. As shown in FIG. 3A, the direction AA2, being perpendicular to the first direction, is chosen to be the second direction. The (a) part of the FIG. 3B shows the side-view of the first trench 101; while the (b) part shows the side-view of the second trenches 111. In the instant embodiment, the second trench 111 has a shallower depth than the first trench 101.

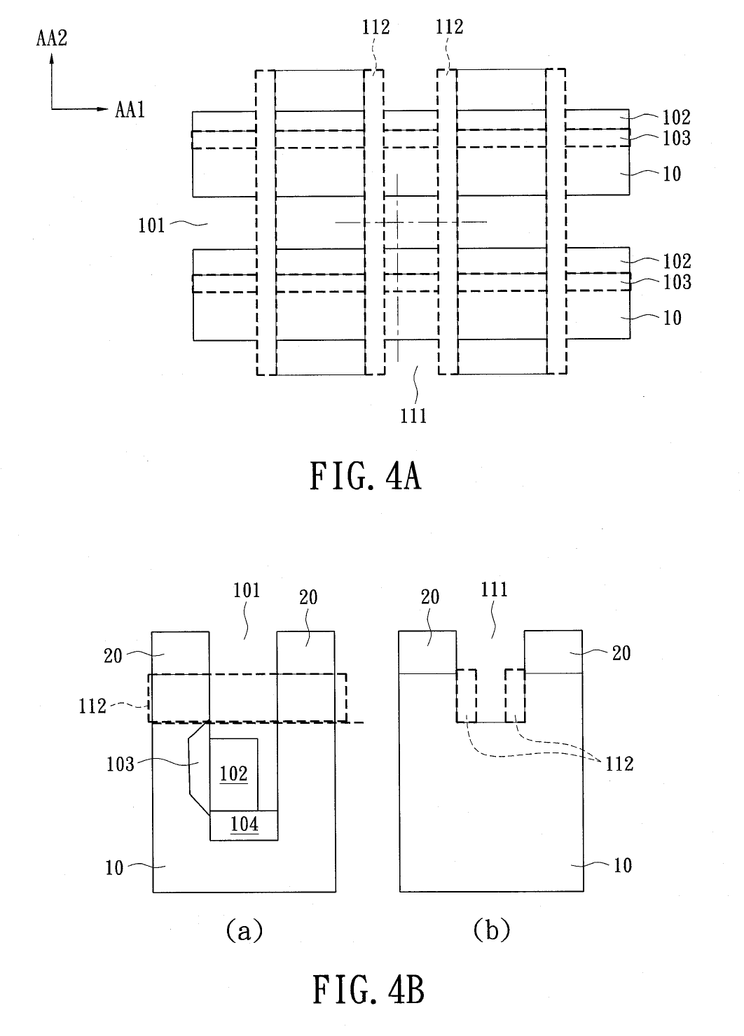

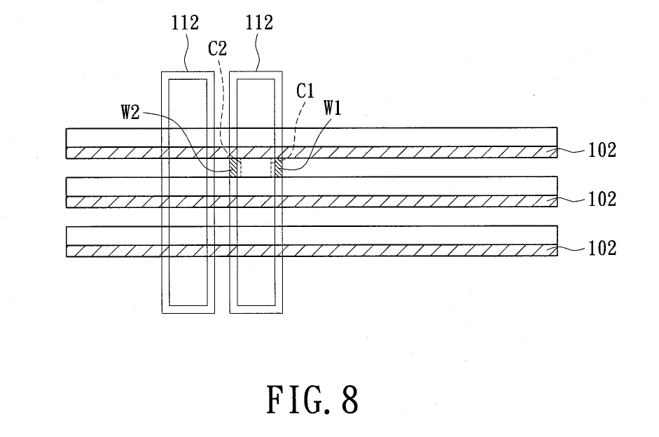

Please refer to FIGS. 4A to 4B. A pair of word lines 112 is formed respectively on the two sidewalls in the second trench 111. Moreover, the pair of word lines 112 joins at the edge of the memory device to form a surrounding word line structure, as shown in FIG. 8. Furthermore, a gate oxide layer may be formed between the word lines 112 and the corresponding side surface of the second trench 111.

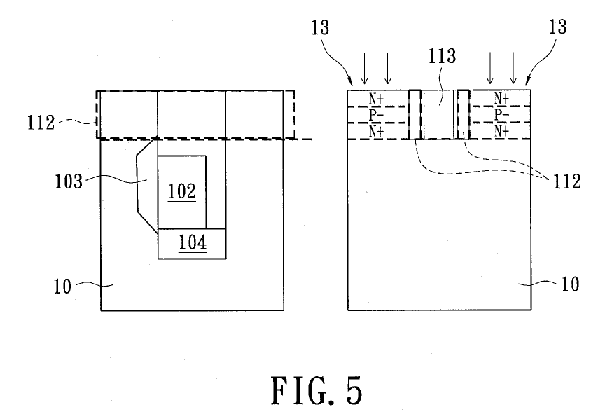

Please refer to FIG. 5. Transistors 13 are disposed on the active area 10. In this step, a filling material 113 is disposed in the second trench 111 between the two word lines 112. Next, the hard mask 20 is removed, and the source and drain terminals are formed on the transistors 13. Thus, the transistor 13 can be controlled by two word lines 112 and one larger bit line 102. As mentioned, the larger bit line 102 provides higher transfer speed, and the two word lines 112 may define two gates and two channels to control the transistor 13. As a result, the switching rate and transfer speed of the memory cell is improved.

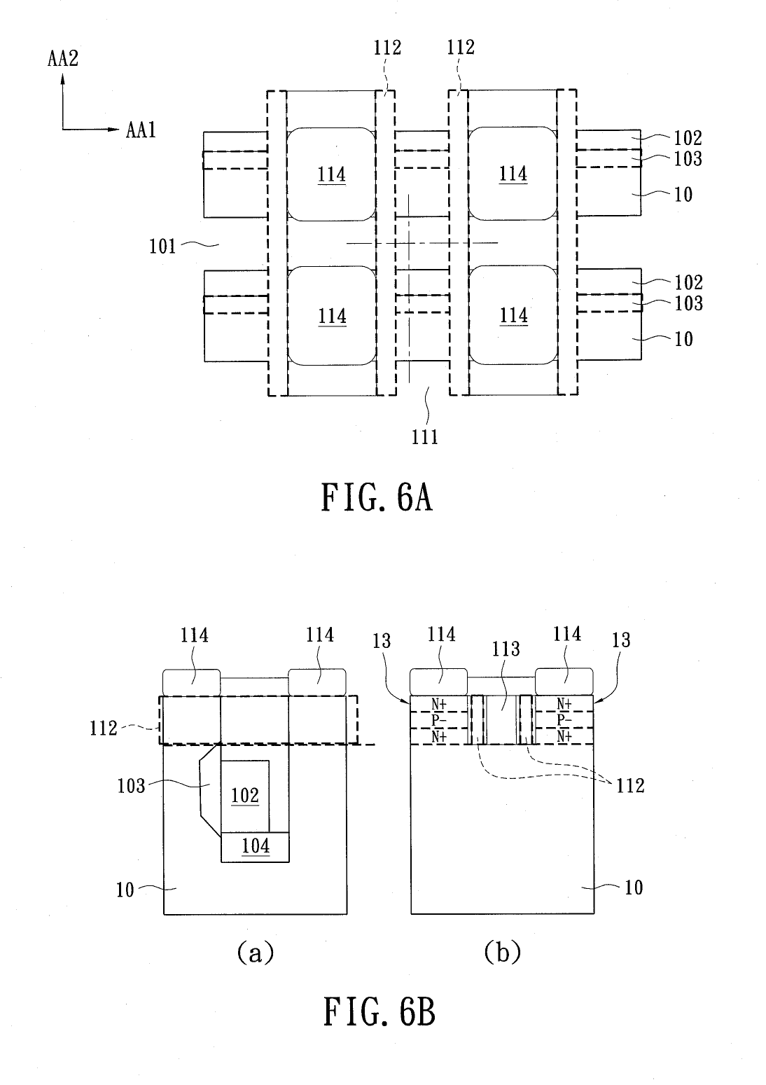

Please refer to FIGS. 6A and 6B; the manufacturing method of the present invention further has a step of forming a pad 114 on the transistor 13. In the embodiment, the pads 114 are arranged in array. Furthermore, the pads 114 may be arranged alternatively, or the pads 114 may have different angle orientations.

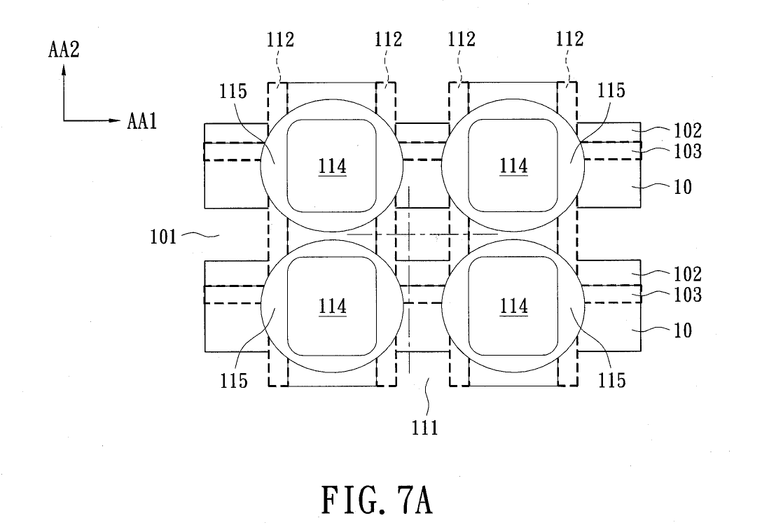

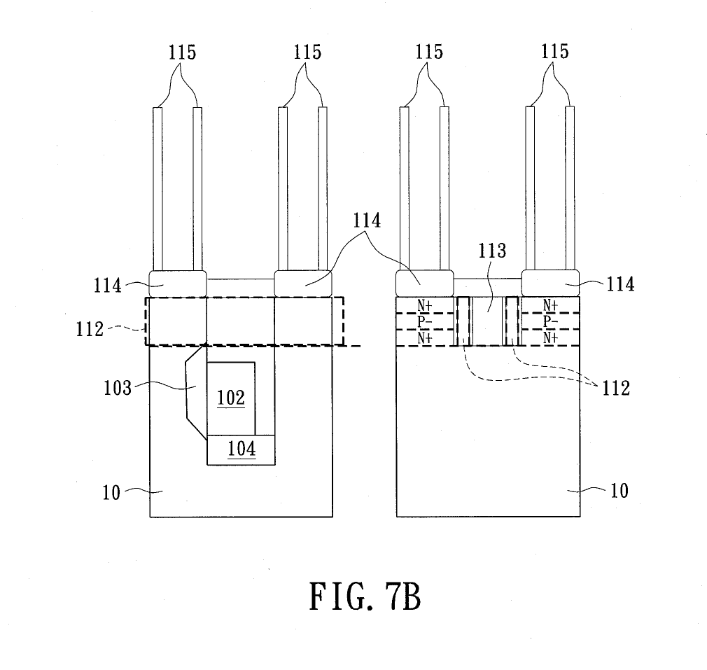

Next step is forming capacitor 115 on the pad 114, as shown in FIGS. 7A and 7B. In the embodiment, the capacitor 115 may be a double side capacitor.

Accordingly, the memory cell has an active area 10, the first trenches 101 extending in the first direction, the second trenches 111 extending in the second direction and transistors 13. The first trench 101 has a single bit line 102 formed on a side thereof, and the second trench 111 has word lines 112 respectively formed on two sides thereof. Therefore, each transistor 13 is controlled by a bit line 102 and two word lines 112. The speed of the transistor 13 can be improved because of the lower resistance of the larger bit line 102 and the two channels C1, C2 (as shown in FIG. 8) defined by the two word lines 112.

Furthermore, the memory cell of the present invention is a 4F2 memory cell, wherein “F” represents the minimum process width. In addition, the memory cell of the present invention has double gate W1, W2 (i.e., word lines 112) which forms a surrounding gate structure. The double gate W1, W2 defines two channels C1, C2 for increasing the switch rate of the transistor 13.

### SUMMARY

1. The present method is used for forming a single bit line on a side of the first trench. Comparing to the traditional first trench having two bit lines, the bit line of the present invention has larger area, which results in a lower resistance. Therefore, the memory cell has higher speed due to the larger bit line.

2. The present invention provides a memory cell having a double side gate (i.e., surrounding gate). The word lines formed on two sides of the transistor defines two channels. Therefore, the switch rate of the transistor can be increased.

What is claimed is:

1. A memory cell with surrounding word line structures, comprising:
an active area;
a plurality of first trenches formed on the active area extending in a first direction,
wherein each first trench has a bit line on a sidewall therein;
a plurality of second trenches formed on the active area extending in a second direction,
wherein each second trench has two word lines formed correspondingly on the sidewalls in the second trench; and
a plurality of transistors formed on the active area,
wherein each transistor is controlled by the bit line and the two word lines,
wherein the word lines are arranged into surrounding word line structures, and
wherein each the transistor is controlled by two gates defined by the two word lines.

2. The cell with surrounding word line structures according to claim 1, wherein each the second trench has a shallower depth than each the first trench.

3. The cell with surrounding word line structures according to claim 1, wherein each the first trench further has an out-diffusion junction on the side thereof and the out-diffusion junction corresponds to the bit line.

4. The cell with surrounding word line structures according to claim 1, wherein each the first trench further has a shallow trench isolation (STI) on a bottom thereof and the bit line is formed on the shallow trench isolation.

5. The cell with surrounding word line structures according to claim 1, wherein each transistor has a pad thereon, and the pad further has a capacitor thereon.

6. A manufacturing method for a cell with surrounding word line structures, comprising steps of:
providing an active area;
forming a plurality of first trenches on the active area,
wherein the first trenches extend in a first direction,
forming a bit line on a sidewall in the first trench;
forming a plurality of second trenches in the active area
wherein the second trenches extend in a second direction,
forming two word lines respectively on the sidewalls of the second trench; and
forming a plurality of transistors on the active area;
wherein each transistor is controlled by two gates defined by the two word lines and one of the bit lines.

7. The method according to claim 6, wherein the step of forming a bit line on a side of each the first trench has a trench sidewall implant step and an etch back step.

8. The method according to claim 6, further comprising a step of forming an out-diffusion junction in the side of each the first trench after the step of forming a bit line on a side of each the first trench, wherein the out-diffusion junction corresponds to the bit line.

9. The method according to claim 6, wherein each the second trench has a shallower depth than each the first trench in the step of forming a plurality of second trenches in the active area.

10. The method according to claim 6, further comprising steps of forming a pad on each the transistor and forming capacitor on the pad after the step of forming a plurality of transistors.
